(19) United States
(12) Patent Application Publication
(10) Pub. No.: US 2022/0357114 A1
(43) Pub. Date: Nov. 10, 2022

(54) HIGH CONDUCTANCE FIN

(71) Applicant: Lenovo (Singapore) Pte. Ltd., Singapore (SG)

(72) Inventors: Tsutomu Chonan, Kanagawa (JP); Shogo Akiyama, Kanagawa (JP); Yusuke Onoue, Kanagawa (JP)

(73) Assignee: Lenovo (Singapore) Pte. Ltd., Singapore (SG)

(21) Appl. No.: 17/313,425

(22) Filed: May 6, 2021

(51) Int. Cl. F28F 3/08; F28D 15/02; B21D 53/02

(52) U.S. Cl. CPC F28F 3/08; F28D 15/02; B21D 53/022

(57) ABSTRACT

A stacked conductance fin assembly, that is connected to a heatpipe and an exhaust fan of a computing device, includes: a plurality of fins that are partially overlapped and stacked in a linear array along a first axis of the stacked conductance fin assembly. Overlapping regions of the plurality of fins form two parallel structural walls along the first axis. The overlapping regions overlap along a second axis of the stacked conductance fin assembly, the second axis being perpendicular to the first axis. Each of the plurality of fins includes: a main surface that extends along the second axis between two outermost ends of the main surface; two walls that extend along the first axis, each wall extending from each of the outermost ends of the main surface, respectively; and two offset walls that extend along the first axis, each offset wall extending from each wall, respectively.

### BACKGROUND

Computing devices regulate the temperature of various electronic components using one or more heat exchangers (e.g., to protect the electronic components from damage and to ensure stable performance). For example, a consumer laptop may use a heatpipe to transfer thermal energy from one or more of the processors to a “caterpillar” style stacked conductance fin assembly mounted in the path of an exhaust fan to dissipate the thermal energy of the processors outside of the laptop chassis. However, the cavities (i.e., gaps) in the stacked conductance fin assembly are typically a bottleneck for the air flow from the exhaust fan in compact heat exchanger systems (e.g., in personal laptops). Therefore, regulating the temperature of the electronic components is limited by the volume of air passing through the stacked conductance fin assembly.

### SUMMARY

In general, one or more embodiments of the invention relate to a stacked conductance fin assembly that connects to a heatpipe and an exhaust fan of a computing device. Embodiments of the stacked conductance fin assembly include a plurality of fins that are partially overlapped and stacked in a linear array along a first axis of the stacked conductance fin assembly. Overlapping regions of the plurality of fins form two parallel structural walls along the first axis. The overlapping regions overlap along a second axis of the stacked conductance fin assembly, the second axis being perpendicular to the first axis. Each of the plurality of fins includes: a main surface that extends along the second axis between two outermost ends of the main surface; two walls that extend along the first axis, each wall extending from each of the outermost ends of the main surface, respectively; and two offset walls that extend along the first axis, each offset wall extending from each wall, respectively, such that planes of the two offset walls are offset from planes of the two walls along the second axis. Furthermore, in each of the overlapping regions, the two walls of one of the plurality of fins overlap with the two offset walls of another adjacent one of the plurality of fins.].

In general, one or more embodiments of the invention relate to a method of manufacturing a stacked conductance fin assembly that is configured to be connected to a heatpipe and an exhaust fan of a computing device. The method includes: disposing a plurality of fins in a linear array along a first axis; stacking overlapping regions of the plurality of fins to form two parallel structural walls along the first axis. Each of the plurality of fins includes: a main surface that extends along a second axis between two outermost ends of the main surface, the second axis being perpendicular to the first axis; two walls that extend along the first axis, each wall extending from each of the outermost ends of the main surface, respectively; and two offset walls that extend along the first axis, each offset wall extending from each wall, respectively, such that planes of the two offset walls are offset from planes of the two walls along the second axis. The overlapping regions overlap along the second axis, and in each of the overlapping regions, the two walls of one of the plurality of fins overlap with the two offset walls of another adjacent one of the plurality of fins.].

Other aspects of the invention will be apparent from the following description and the appended claims.

### BRIEF DESCRIPTION OF DRAWINGS

FIG. 1 shows a heat exchanger in accordance with one or more embodiments of the invention.

FIG. 2A shows a perspective view of a comparative example of a fin.

FIG. 2B shows a perspective view of a comparative example of a fin assembly.

FIG. 3A shows a perspective view of a high conductance fin according to one or more embodiments of the claimed invention.

FIG. 3B shows a perspective view of a high conductance fin assembly according to one or more embodiments of the claimed invention.

FIG. 3C shows a perspective view of an edge fin according to one or more embodiments of the claimed invention.

FIG. 4A shows a cross-section view of a comparative example of a fin assembly.

FIG. 4B shows a cross-section view of a stacked conductance fin assembly according to one or more embodiments of the claimed invention.

FIG. 5 shows a flowchart of a method of manufacturing a heat exchanger in accordance with one or more embodiments of the claimed invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In general, embodiments of the invention provide a stacked conductance fin assembly, a heat exchanger, and a method of producing a heat exchanger for dissipating thermal energy. More specifically, embodiments of the invention are directed to a stacked conductance fin assembly for dissipating heat in computing devices (e.g., a personal computer, personal laptop, smart phone, personal digital assistant, tablet computer, other mobile device, server, etc.). A computing device may include one or more stacked conductance fin assemblies in one or more heat exchangers to regulate internal and external temperatures of the computing device.

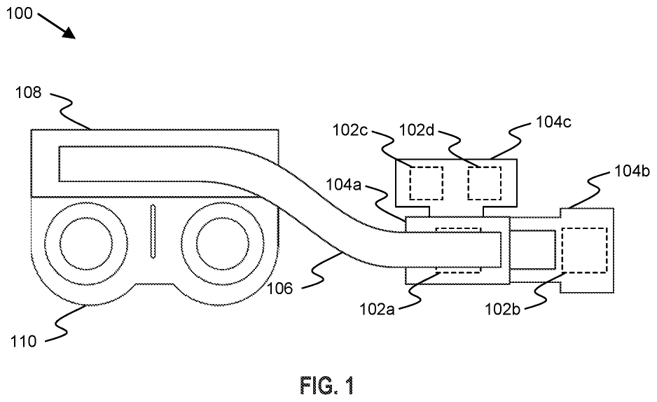

FIG. 1 shows a heat exchanger 100 in accordance with one or more embodiments of the invention. As shown in FIG. 1, the heat exchanger 100 may be connected to one or more electronic components 102a-d and one or more heat sink pads 104a-c. The heat exchanger 100 has multiple components, and may include, for example, a heatpipe 106, a stacked conductance fin assembly 108, and an exhaust fan 110. Each of these components is discussed in further detail below.

The heat exchanger 100 may be connected to one or more electronic components 102a, 102b, 102c, 102d. Each of the electronic components 102a-d may be any hardware component of a computing device, e.g., a computer processing unit (CPU), graphics processing unit (GPU), an integrated circuit, conductive trace, resistor, capacitor, inductor, transistor, battery, light emitting diode (LED), etc., or any combination thereof.

Each of the electronic components 102a-d may include one or more heat sink pads 104a-c. Each of the heat sink pads 104a-c is a thermally conductive structure that is thermally connected to one or more of the electronic components 102a-d and to the heatpipe 106. For example, the heat sink pad 104a may be a metal (e.g., copper) pad connected to an electronic component 102a with a thermally conductive filler (e.g., thermal paste, thermally conductive adhesive). In another example, the heat sink pad 104b may be a metal structure that is soldered to an electronic component 102b on a circuit board of the computing device. In one or more embodiments, each of the heat sink pads 104a-c are thermally connected to each other. For example, the heat sink pads 104a-c may be formed from a single contiguous metal structure or may be connected by soldering. Each heat sink pad 104a-c may be any thermally conductive structure of a computing device and is not limited to the examples above.

The heat exchanger 100 includes a heatpipe 106. The heatpipe 106 may be a thermally conductive structure that is connected to the one or more heat sink pads 104a-c and to the stacked conductance fin assembly 108. For example, the heatpipe 106 is a sealed pipe containing a working fluid that absorbs heat from one end of the heatpipe 106 and dissipates heat at another end of the heatpipe 106 via a phase transition of the working fluid. Alternatively, the heatpipe 106 may be an extension of the one or more heat sink pads 104a-c. The heatpipe 106 may be any thermally conductive structure of a computing device and is not limited to the examples above.

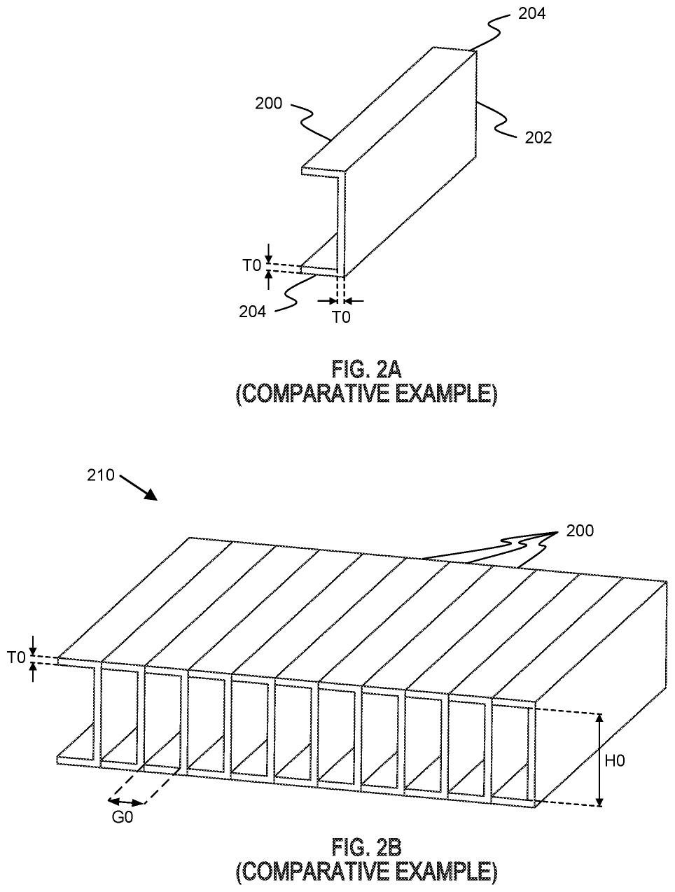

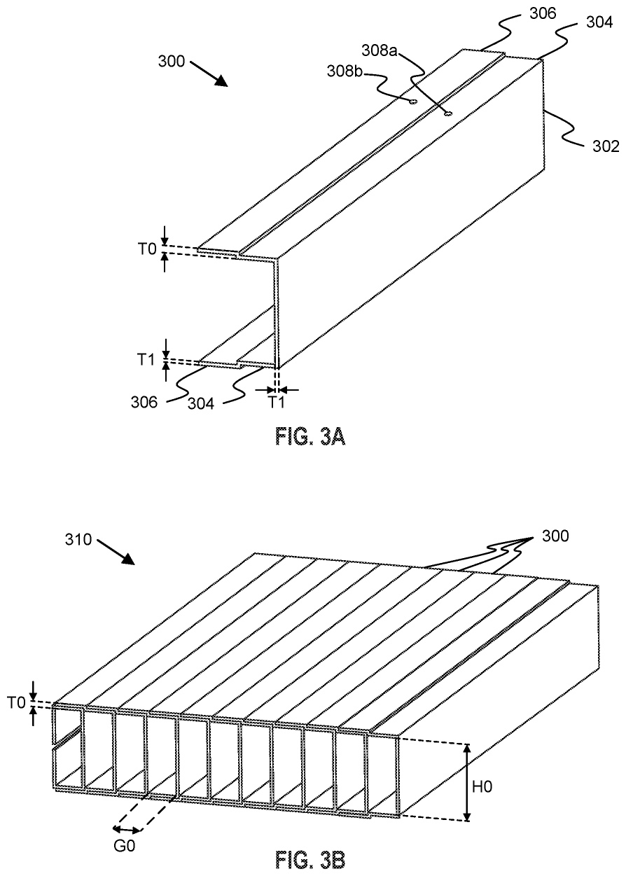

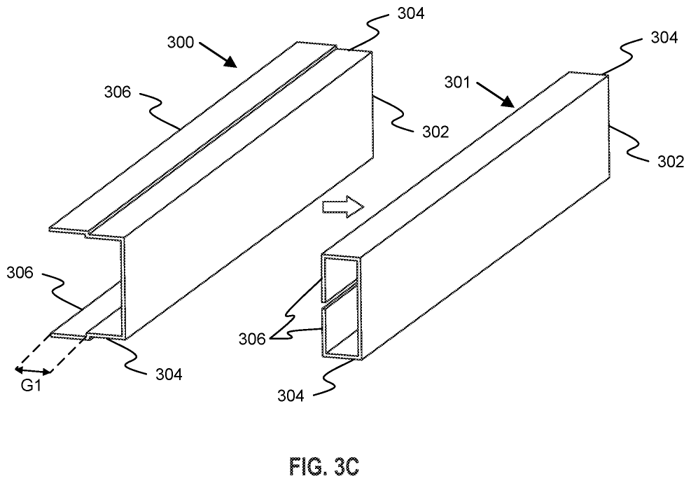

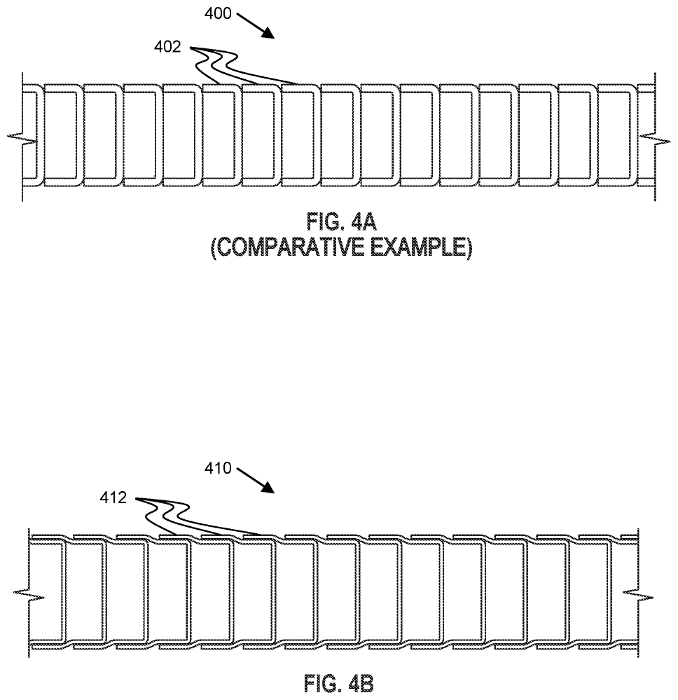

Furthermore, the heat exchanger 100 includes a stacked conductance fin assembly 108. The stacked conductance fin assembly 108 thermally connects the heatpipe 106 and air flow from the exhaust fan 110. The stacked conductance fin assembly 108 may include a plurality of fins that are stacked in an array to form a plurality of cavities between the fins. The airflow from the exhaust fan 110 passes through the cavities while absorbing thermal energy from the stacked conductance fin assembly 108 to dissipate the thermal energy to the exterior of the heat exchanger 100. Comparative examples of a fin and a fin assembly are discussed in further detail below with reference to FIGS. 2A-2B and 4A. Examples of a fin and a stacked conductance fin assembly according to one or more embodiments of the claimed invention are discussed in further detail below with reference to FIGS. 3A-3C and 4B.

In addition, the heat exchanger 100 includes an exhaust fan 110. The exhaust fan 110 forces air through the stacked conductance fin assembly 108 to dissipate heat to the exterior of the heat exchanger 100. The exhaust fan 110 may be one or more radial fans operated (e.g., controlled by a processor) at variable speeds to control the volume and the pressure of the air flowing through the stacked conductance fin assembly 108. The exhaust fan 110 may be any forced air system and is not limited to the examples above.

FIG. 2A shows a perspective view of a comparative example fin 200, which is a metal bracket with a c-shape in a cross-section view along its depth. The comparative example fin 200 comprises a main surface 202 that extends in a vertical direction and two planar walls 204 disposed at opposing ends of the main surface and that extend in a horizontal direction perpendicular to the main surface. For reference, the horizontal direction in the cross-section view of the comparative example fin 200 is along a first axis, the vertical direction in the cross-section view of the comparative example fin 200 is along a second axis, and the horizontal direction along the depth of the comparative example fin 200 is along a third axis. The comparative example fin 200 is formed from a single sheet of metal with a uniform thickness such that the main surface 202 and the two planar walls 204 have the same thickness T0.

As discussed below with reference to FIG. 2B, stacking a plurality of comparative example fins 200 along the first axis forms a comparative example fin assembly 210 with a plurality of cavities.

FIG. 2B shows a perspective view of a comparative example fin assembly 210. The comparative example fin assembly 210 has a repeating unit cell geometry where each unit cell includes a cavity of width G0 and height H0 forming an open area through which the air flow from the exhaust fan 110 can pass.

As discussed below with reference to FIGS. 3A-3B, embodiments of the present invention advantageously improve wind volume throughput of the exhaust fan 110 by maximizing an open area ratio of the stacked conductance fin assembly 108.

FIG. 3A shows a perspective view of a high conductance fin 300 according to one or more embodiments of the claimed invention. Each fin 300 is a bracket with an extended c-shape in a cross-section view along the depth of the fin 300. The fin 300 comprises a main surface 302 that extends along the second axis (i.e., vertically along the height of the fin 300), two walls 304 disposed at opposing ends of the main surface 302 and that extend along the first direction (i.e., horizontally along the width of the fin 300), and two offset walls 306 that extend, also along the first direction, from the ends of the two walls 304, respectively. Each of the offset walls 306 are offset from each of the walls 304 such that planes of the two offset walls 306 are offset from planes of the two walls 304 along the second axis. The planes of the offset walls 306 are parallel with the planes of the walls 304 along the first and third axes.

In one or more embodiments, each of the two offset walls 306 is offset from its connected wall 304 on a side that is farther from the main surface 302, as shown in FIG. 3A. However, the offset walls 306 are not limited to this configuration. For example, in one or more embodiments, each offset wall 306 may be offset from its connected wall 304 on a side that is closer to the main surface 302. Alternatively, each offset wall 306 may be offset from its respective wall 304 in a same direction along the second axis.

In general, the offset walls 306 of a plurality of fins 300 are all offset using the same configuration such that the plurality of fins 300 can be stacked by overlapping the offset walls 306 and walls 304 of adjacent fins 300 to form a stacked conductance fin assembly 310, as shown in FIG. 3B.

In one or more embodiments, each fin 300 is formed from a single sheet of material with a uniform thickness T1 such that the main surface 302, the two walls 304, and the two offset walls 306 have the same thickness T1. The material thickness required to maintain structural integrity (e.g., rigidity, stability, etc.) may vary depending on the material used and the type/model of computing device. Advantageously, the above configuration of fin 300 can provide the necessary structural integrity with a thickness T1 that is only half of the thickness T0 of the comparative example fin 200 because each overlapping region has double the thickness of each fin 300. Therefore, if a comparative example fin 200 has a thickness of T0=0.2 mm, in one or more embodiments, each fin 300 may be formed from a sheet with a uniform thickness T1=0.1 mm.

In one or more embodiments, each fin 300 includes at least one pair of latches 308a, 308b that connect adjacent fins 300. The latch 308a may be disposed on at least one of the two walls 304 at a predetermined distance from an end of the fin 300 along the third axis. Similarly, the corresponding latch 308b may be disposed on at least one of the two offset walls 306 at the predetermined distance from the end of the fin 300 along the third axis. When a first fin 300 is stacked with a second fin 300, by overlapping the offset walls 306 of the second fin 300 onto the walls 304 of first fin 300, the pair of latches 308a, 308b overlap in a direction along the second axis to attach the first fin 300 to the second fin 300.

In one or more embodiments, the latches 308a, 308b may be hook attachments that connect. For example, the latch 308b may be a protrusion of material from the offset wall 306 of the second fin 300 (e.g., a tab of material formed by punching a hole or pattern into the offset wall 306, an indentation extending through the offset wall 306 in the direction along the second axis, a foreign material adhered to the surface of the offset wall 306) that is configured to extend into the latch 308a (e.g., a hole or indentation) formed in the wall 304 of the first fin 300.

Alternatively, in one or more embodiments, the walls 304 of the first fin 300 and the offset walls 306 of the second fin 300 may be appropriately dimensioned to press fit together. In one or more embodiments, the walls 304 and/or offset walls 306 of each fin 300 may be biased inward toward the main surface 302 to strengthen the press fit by providing additional pressure when overlapping the walls 304 of the first fin 300 and the offset walls 306 of the second fin 300.

Any other appropriate method or mechanism for securing adjacent fins 300 together may be used. For example, the fins 300 may be soldered or brazed together at predetermined points, continuously along the length of the fins 300, or any combination thereof. Alternatively, an adhesive may be used to secure the fins 300 together. The adhesive may comprise a thermally conductive material and may be used to connect the fins 300 together and to simultaneously connect the stacked conductance fin assembly 310 to other structures.

FIG. 3B shows a perspective view of a stacked conductance fin assembly 310 according to one or more embodiments of the claimed invention. The stacked conductance fin assembly 310 has a repeating unit cell geometry (except at the outermost ends) where each unit cell includes an open area through which the air flow from the exhaust fan 110 can pass. The open area of each unit cell of the stacked conductance fin assembly 310 is determined by multiplying the height H0 of each cavity (i.e., the length of the main surface 302 along the second axis) and the width G0 of each cavity (i.e., the length of only the walls 304 along the first axis because the offset walls 306 extend into the unit cell of an adjacent fin 300 by overlapping the walls 304). The cross-sectional area of the unit cell in the stacked conductance fin assembly 310 is determined by multiplying the height of each fin 300 (i.e., the height of the cavity plus the thickness of the two walls 304 and two offset walls 306, H0+4*T1) and the total width of each unit cell (i.e., the width of the cavity plus the thickness of the main surface 302, G0+T1).

The inventors have discovered that the open area ratio (i.e., the ratio of the open area and the cross-sectional area of the unit cell geometry of the stacked conductance fin assembly 310) is a critical parameter in determining the efficacy of a stacked conductance fin assembly 108. The open areas in a stacked conductance fin assembly 108 are a bottleneck for the air flow from the exhaust fan 110. This bottleneck in the wind volume throughput can limit the amount of thermal energy dissipated by a heat exchanger 100. However, the configuration of the fin 300 advantageously improves the wind volume throughput from the exhaust fan 110 by increasing the open area ratio.

By way of example, when used for a notebook computer, a comparative example fin 200 typically has a thickness of T0=0.2 mm and a cavity width of G0=1.0 mm to maintain structural integrity of the comparative example fin assembly 210. Accordingly, the open area of the comparative example unit cell in the comparative example fin assembly 210 is the height H0 of each cavity (i.e., the length of main surface 202 along the second axis) multiplied by the width G0 of each cavity (i.e., the length of planar walls 204 along the first direction). The cross-sectional area of the comparative example unit cell is the height of each comparative example fin 200 (i.e., the height of the cavity plus the thickness of the two planar walls 204, H0+2*T0) multiplied by the width of each comparative example fin 200 (i.e., the width of the cavity plus the thickness of the main surface 202, G0+T0).

Therefore, in one or more embodiments where T1=T0/2=0.1 mm, width G0=1.0 mm, and height H0=3.0 mm, the open area ratio of the comparative example fin assembly 210 is (G0*H0)/((G0+T0)*(H0 +2*T0))=0.73 while the open area ratio of the stacked conductance fin assembly 310 is (G0*H0)/((G0+T1)*(H0+2*T0))=0.80. Because the thickness T1=1.0 mm of the main surface 302 of the fins 300 is less than the thickness T0=2.0 mm of the main surface 202 in the comparative example fins 200, the open area ratio of the stacked conductance fin assembly 310 that is greater than the open area ratio of the comparative example fin assembly 210. The inventors confirmed that the larger open area ratio in the stacked conductance fin assembly 310 resulted in a 5% increase in the wind volume throughput compared to the comparative example fin assembly 210.

Furthermore, as discussed above with reference to FIG. 3A, while the reduced thickness of the main surface 302 improves the open area ratio and wind volume throughput, the overlapping region of the two walls 304 and the two offset walls 306 ensure structural stability of the stacked conductance fin assembly 310 by forming two parallel structural walls, at the top and bottom of the stacked conductance fin assembly 310. In one or more embodiments where the thickness of each fin 300 is T1=0.1 mm and a standard cavity width G0=1.0 mm is used, the structural walls of the stacked conductance fin assembly 310 are not any more prone to collapse than the structural walls of thickness T0=0.2 mm in the comparative example fin assembly 210. Therefore, the configuration of the fins 300 with a reduced thickness T1 simultaneously provides structural stability while improving the efficacy of the stacked conductance fin assembly 310.

In contrast, increasing the open area ratio of a comparative example fin assembly 210 by simply reducing the thickness T0 of the comparative example fins 200 would negatively affect the structural integrity of the comparative example fin assembly 210. For example, the rigidity of the planar walls 204 that form the upper and lower structural walls of the comparative example fin assembly 210 would be more prone to partial or complete collapse (e.g., folding or crumpling into the cavity region of one or more comparative example fins 200) during assembly or installation of the comparative example fin assembly 210. Any collapsed region in the comparative example fin assembly 210 would reduce the wind volume throughput from the exhaust fan 110 and negatively affect the efficacy of the comparative example fin assembly 210.

FIG. 3C shows a perspective view of an edge fin 301 according to one or more embodiments of the claimed invention. The edge fin 301 is formed by bending the offset walls 306 of a fin 300 to extend toward each other along the second axis. Therefore, the main surface 302, the bent offset walls 306, and the two walls 304 of the edge fin 301 form a cavity that is at least partially closed and that extends along the third axis. As shown in FIG. 3B, when an edge fin 301 is added as the last fin in the stacking direction of a stacked conductance fin assembly 310, the last cavity is at least partially closed by an edge surface that contributes to the transfer of heat to the air flowing through the stacked conductance fin assembly.

In one or more embodiments, the main surface 302 of the edge fin 301 has a length H0 along the second axis and each of the two offset walls 306 has a length G1=H0/2. Therefore, when the two offset walls 306 of the edge fin 301 are bent to extend toward each other along the second axis, the two offset walls 306 connect to form a continuous edge surface of length H0 that extends parallel to the main surface 302. In other words, the main surface 302, the continuous edge surface, and the two walls 304 of the edge fin 301 form a closed cavity that extends along the third axis.

As discussed below with reference to FIGS. 4A-4B and TABLES 1-2, the inventors have performed a series of experiments to compare the efficacy of the comparative example fin assembly 210 and the stacked conductance fin assembly 310. FIG. 4A shows a cross-section view of a comparative example fin assembly 400. The comparative example fins 402 of the comparative example fin assembly 400 have a thickness T0=0.2 mm and form a plurality of cavities with a width G0=1.0 mm and a height H0=3.0 mm. FIG. 4B shows a cross-section view of the stacked conductance fin assembly 410 according to one or more embodiments of the claimed invention. The fins 412 of the stacked conductance fin assembly 410 have a thickness T1=0.1 mm and form a plurality of cavities with a width G0=1.0 mm and a height H0=3.0 mm.

The comparative example fin assembly 400 and the stacked conductance fin assembly 410 were installed into identical heat exchangers inside of identical notebook computers operating under uniform conditions. TABLE 1 shows thermocouple temperature measurements of various internal components and various external positions of the notebook computers. TABLE 2 shows the temperature measurements of various internal electronic components recorded by monitoring the output signal of an integrated thermometer (e.g., a thermistor) within each component. A lower temperature measurement indicates that thermal energy is being dissipated more efficiently from the notebook computer. The temperature data has been calibrated to account for instrument offsets and ambient temperature conditions.

TABLE 1

| | | Temperature (° C.) | | |
|---|---|---|---|---|
| | | Comparative | Fin | |
| | | Example Fin | Assembly | Temperature |
| Measurement Point | | Assembly 400 | 410 | Improvement |
| CPU power | Internal Component 1 | 69.8 | 68.6 | −1.2 |
| | Internal Component 2 | 68.4 | 67.3 | −1.1 |
| | Internal Component 3 | 66.9 | 66.4 | −0.5 |
| | Internal Component 4 | 66.3 | 65.9 | −0.4 |
| | Internal Component 5 | 61.3 | 60.9 | −0.4 |
| | Internal Component 6 | 67.3 | 66.9 | −0.4 |
| | Internal Component 7 | 66.4 | 66 | −0.4 |
| | Internal Component 8 | 63.4 | 63 | −0.4 |
| | Internal Component 9 | 67.3 | 66.9 | −0.4 |
| | Internal Component 10 | 64.6 | 64.2 | −0.4 |
| | Internal Component 11 | 61.6 | 61.3 | −0.3 |
| Charger | Internal Component 12 | 59.5 | 59.1 | −0.4 |
| | Internal Component 13 | 59.3 | 58.9 | −0.4 |
| Memory | Internal Component 14 | 59.1 | 58.5 | −0.6 |
| | Internal Component 15 | 60.4 | 59.9 | −0.5 |
| | Internal Component 16 | 61.4 | 60.9 | −0.5 |
| | Internal Component 17 | 61.7 | 61.2 | −0.5 |
| Wireless | Internal Component 18 | 37.2 | 37.1 | −0.1 |
| Wide Area | | | | |
| Network | | | | |
| Card | | | | |
| Solid State | Internal Component 19 | 51.4 | 51.2 | −0.2 |
| Drive | | | | |
| Controller | | | | |
| Liquid | External Position 3 | 44.4 | 43.8 | −0.6 |
| Crystal | | | | |
| Display | | | | |
| Power | External Position 4 | 38.9 | 38.8 | −0.1 |
| Button | | | | |
| Touchpad | External Position 5 | 29.4 | 29.4 | 0 |
| Cover | External Position 6 | 41.8 | 41.4 | −0.4 |
| | External Position 7 | 56.9 | 56.4 | −0.5 |
| | External Position 8 | 44.9 | 44.4 | −0.5 |
| | External Position 9 | 44.2 | 43.8 | −0.4 |
| | External Position 10 | 50.2 | 49.8 | −0.4 |
| | External Position 11 | 50.6 | 50.1 | −0.5 |
| | External Position 12 | 49.6 | 49.3 | −0.3 |
| | External Position 13 | 32.1 | 32.1 | 0 |
| | External Position 14 | 44.9 | 44.7 | −0.2 |
| | External Position 15 | 51.5 | 51.2 | −0.3 |
| | External Position 16 | 45.6 | 45.3 | −0.3 |
| | External Position 17 | 47.7 | 47.3 | −0.4 |
| | External Position 18 | 46.4 | 45.9 | −0.5 |
| | External Position 19 | 48.7 | 48.2 | −0.5 |
| | External Position 20 | 35.5 | 35.3 | −0.2 |
| | External Position 21 | 32.8 | 32.8 | 0 |

As shown in TABLE 1, the notebook computer with the fins 412 according to one or more embodiments consistently outperformed the notebook computer with the comparative example fins 402. The notebook computer with the stacked conductance fin assembly 410 had lower temperatures for every thermocouple measurement. The skin temperature of the fins 412 was 0.7° C. lower than the skin temperature of the comparative example fins 402, demonstrating more efficient heat transfer to the air flow from the exhaust fan.

TABLE 2

| | Temperature (° C.) | | |
|---|---|---|---|
| | Comparative | Fin | |
| | Example Fin | Assembly | Temperature |
| Measurement Point | Assembly 400 | 410 | Improvement |
| Internal Thermometer 1 | 76.7 | 75.2 | −1.5 |
| Internal Thermometer 2 | 71.7 | 70.2 | −1.5 |
| Internal Thermometer 3 | 35.7 | 35.2 | −0.5 |
| Internal Thermometer 4 | 34.7 | 34.2 | −0.5 |
| Internal Thermometer 5 | 59.7 | 58.2 | −1.5 |
| Internal Thermometer 6 | 51.7 | 51.2 | −0.5 |
| Internal Thermometer 7 | 63.7 | 63.2 | −0.5 |
| Internal Thermometer 8 | 60.7 | 59.2 | −1.5 |
| Internal Thermometer 9 | 37.7 | 37.2 | −0.5 |

Similarly, TABLE 2 also shows that the notebook computer with the fins 412 according to one or more embodiments consistently outperformed the notebook computer with the comparative example fins 402. The notebook computer with the stacked conductance fin assembly 410 had lower temperatures for each of the nine internal thermometer measurements.

Furthermore, the notebook computer with the fins 412 demonstrated a 0.5 W improvement in power consumption compared to the notebook computer with the comparative example fins 402, which is significant fraction of the power consumed by a typical CPU (e.g., 15-20 W). In addition, the notebook computer with the fins 412 produced 5% more air throughput compared to the notebook computer with the comparative example fins 402.

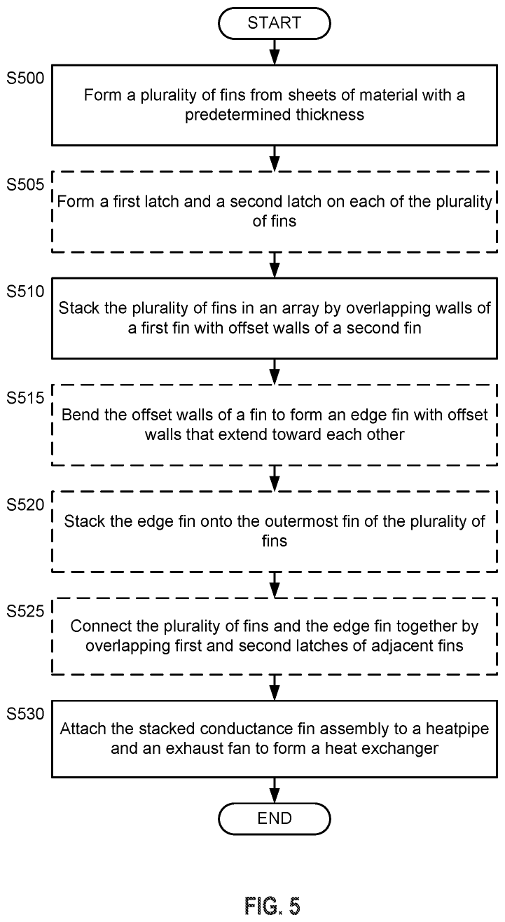

FIG. 5 shows a flowchart of a method of manufacturing a heat exchanger in accordance with one or more embodiments of the invention. One or more of the individual processes shown in FIG. 5 may be omitted, repeated, and/or performed in a different order than the order shown in FIG. 5. Accordingly, the scope of the invention should not be limited by the specific arrangement as depicted in FIG. 5.

At S500, a plurality of fins 300 are formed form sheets of material with a predetermined thickness. In one or more embodiments, the sheets may be metal or any other material with sufficient thermal conductance. In one or more embodiments, the fins 300 are formed by stamping blanks from a copper sheet and bending the blanks to form the main surface 302, the walls 304, and the offset walls 306.

At S505, latches 308a, 308b may optionally be formed on each fin 300 such that a plurality of fins 300 may be connected. In one or more embodiments, the latches 308a, 308b may be created by punching a hole or pattern into the walls 304 and/or offset walls 306, depending on whether the offset walls 306 are offset toward or away from the main surface 302 relative to the walls 304. The punched hole or pattern may form a bendable tab of material that is configured to be bent into a corresponding latch of an adjacent fin 300. In one or more embodiments, the latches 308a, 308b may be created by indenting surfaces of the walls 304 and/or offset walls 306. However, the method of forming the latches 308a, 308b are not limited to the above and any appropriate latching system may be disposed on each fin 300.

At S510, the plurality of fins 300 are stacked in an array by overlapping walls 304 of a first fin 300 with offset walls of a second fin 300. In one or more embodiments, multiple rows (i.e., linear arrays) of stacked fins 300 may be combined into a two-dimensional array to form a larger stacked conductance fin assembly 310.

At S515, an edge fin 301 is optionally formed by bending the offset walls 306 of a fin 300 such the offset walls 306 extend toward each other.

At S520, the edge fin 301 is optionally stacked onto the outermost fin 300 of the plurality of fins 300 by overlapping the walls 304 of the edge fin 301 with the offset walls 306 of the outermost fin 300 of the plurality of fins 300.

At S525, the plurality of fins 300 and the edge fin 301 are optionally connected by overlapping the latches 308a, 308b of adjacent fins. Alternatively, the plurality of fins 300 may be press fit together. In one or more embodiments, the plurality of fins 300 and the edge fin 301 are made of copper sheets and are brazed or soldered together.

At S530, the stacked conductance fin assembly 310 is attached to a heatpipe 106 and an exhaust fan 110 to form a heat exchanger 100. In one or more embodiments, the stacked conductance fin assembly 310 is attached to the heatpipe 106 with a thermally conductive material (e.g., solder, thermal paste, thermally conductive tape).

One or more of the embodiments of the invention may have one or more of the following improvements to heat exchangers in computing devices: a larger open area ratio to facilitate more wind volume from an attached exhaust fan; and reducing power consumption by lower operating temperatures of processors and internal electronic components (e.g., CPUs and GPUs). These advantages demonstrate a practical application by improving resource consumption and performance of computer hardware systems.

Although the disclosure has been described with respect to a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. A stacked conductance fin assembly connected to a heatpipe and an exhaust fan of a computing device, the stacked conductance fin assembly comprising:
a plurality of fins that are partially overlapped and stacked in a linear array along a first axis of the stacked conductance fin assembly, wherein
overlapping regions of the plurality of fins form two parallel structural walls along the first axis,
the overlapping regions overlap along a second axis of the stacked conductance fin assembly, the second axis being perpendicular to the first axis,
each of the plurality of fins comprises:
a main surface that extends along the second axis between two outermost ends of the main surface;
two walls that extend along the first axis, each wall extending from each of the outermost ends of the main surface, respectively; and
two offset walls that extend along the first axis, each offset wall extending from each wall, respectively, such that planes of the two offset walls are offset from planes of the two walls along the second axis, and
in each of the overlapping regions, the two walls of one of the plurality of fins overlap with the two offset walls of another adjacent one of the plurality of fins.

2. The stacked conductance fin assembly of claim 1, wherein
in each fin of the plurality of fins, each of the two offset walls is offset from each of the two walls on a side farther away from the main surface.

3. The stacked conductance fin assembly of claim 1, wherein
the plurality of fins includes an edge fin disposed as the outermost edge of the plurality of fins along the first axis,
the edge fin comprises:
a main surface that extends along the second axis between two outermost ends of the main surface;
two walls that extend along the first axis, each wall extending from each of the outermost ends of the main surface, respectively; and
two offset walls that extend toward each other along the second axis, each offset wall extending from each wall, respectively.

4. The stacked conductance fin assembly of claim 1, wherein
each fin of the plurality of fins is formed of a metal sheet with a predetermined thickness,
in each fin of the plurality of fins, each of the main surface, the two walls, and the two offset walls have the same predetermined thickness, and
a thickness of the overlapping regions is twice the predetermined thickness.

5. The stacked conductance fin assembly of claim 1, wherein
each of the plurality of fins further comprises:
a first latch disposed on at least one of the two walls; and
a second latch disposed on at least one of the two offset walls,
the first latch and the second latch are disposed at a predetermined distance from an
opening of the stacked conductance fin assembly along a third axis perpendicular to the first axis and the second axis, and
in each of the overlapping regions, the first latch of one of the plurality of fins and the second latch of another adjacent one of the plurality of fins overlap in a direction along the second axis.

6. The stacked conductance fin assembly of claim 5, wherein
the first latch has a hole,
the second latch comprises a tab that is configured to be bent in the direction along the second axis, and
in each of the overlapping regions, the tab of the second latch is bent to extend into the hole of the first latch.

7. The stacked conductance fin assembly of claim 5, wherein
the first latch has an indentation,
the second latch comprises a protrusion that protrudes in the direction along the second axis, and
in each of the overlapping region, the protrusion of the second latch rests in the indentation of the first latch.

8. The stacked conductance fin assembly of claim 3, wherein
in each of the plurality of fins:
the main surface extends a length H0 along the second axis,
each of the two walls extend a length G0 along the first axis, and
and Expression (1) is satisfied:
G0≤H0/2 . . . (1).

9. The stacked conductance fin assembly of claim 8, wherein
in the edge fin:
the main surface extends the length H0 along the second axis,
each of the two offset walls extend a length G1 along the second axis, and
Expression (2) is satisfied:
G1=H0/2 . . . (2),
such that the two offset walls of the edge fin that extend toward each other along the second axis and connect to form an edge surface that extends along the second axis, and
the main surface, the edge surface, and the two walls of the edge fin form a closed cavity that extends along a third axis of the stacked conductance fin assembly, the third axis being perpendicular to the first axis and the second axis.

10. A method of manufacturing a stacked conductance fin assembly configured to be connected to a heatpipe and an exhaust fan of a computing device, the method comprising:
disposing a plurality of fins in a linear array along a first axis, wherein each of the plurality of fins comprises:
a main surface that extends along a second axis between two outermost ends of the main surface, the second axis being perpendicular to the first axis;
two walls that extend along the first axis, each wall extending from each of the outermost ends of the main surface, respectively; and
two offset walls that extend along the first axis, each offset wall extending from each wall, respectively, such that planes of the two offset walls are offset from planes of the two walls along the second axis; and
stacking overlapping regions of the plurality of fins to form two parallel structural walls along the first axis, wherein
the overlapping regions overlap along the second axis, and
in each of the overlapping regions, the two walls of one of the plurality of fins overlap with the two offset walls of another adjacent one of the plurality of fins.

11. The method of claim 10, wherein
in each fin of the plurality of fins, each of the two offset walls is offset from each of the two walls on sides farther away from the main surface.

12. The method of claim 10, wherein
the plurality of fins includes an edge fin,
the method further comprises disposing the edge fin as the outermost edge of the plurality of fins along the first axis, and
the edge fin comprises:
a main surface that extends along the second axis between two outermost ends of the main surface;
two walls that extend along the first axis, each wall extending from each of the outermost ends of the main surface, respectively; and
two offset walls that extend toward each other along the second axis, each offset wall extending from each wall, respectively.

13. The method of claim 10, further comprising:
forming each fin of the plurality of fins by bending a metal sheet that has a predetermined thickness, wherein
in each fin of the plurality of fins, each of the main surface, the two walls, and the two offset walls have the same predetermined thickness, and
a thickness of the overlapping regions is twice the predetermined thickness.

14. The method of claim 10, further comprising:
in each of the plurality of fins, disposing:
a first latch on at least one wall of the two walls; and
a second latch on at least one offset wall of the two offset walls, wherein
the first latch and the second latch are disposed a predetermined distance from an opening of the stack conductance fin assembly along a third axis perpendicular to the first axis and the second axis; and
overlapping the first latch of one of the plurality of fins and the second latch of another adjacent one of the plurality of fins in a direction along the second axis.

15. The method of claim 14, further comprising:
in disposing the first latch, creating a hole in the at least one wall;
in disposing the second latch, creating a tab that is configured to be bent in the direction along the second axis on the at least one offset wall; and
bending the tab of the second latch into the hole of the first latch.

16. The method of claim 14, further comprising:
in disposing the first latch, creating an indentation in the at least one wall,
in disposing second latch, creating a protrusion that protrudes in the direction along the second axis on the at least one offset wall; and
disposing the protrusion of the second latch in the indentation of the first latch.

17. The method of claim 12, further comprising:
forming each of the plurality of fins such that Expression (1) is satisfied:
G0≤H0/2 . . . (1)
where,
H0 is a length of the main surface along the second axis, and
G0 is a length of each of the two walls along the first axis.

18. The method of claim 17, further comprising:
in forming the edge fin, bending the two offset walls of the edge fin to extend toward each other along the second axis to form an edge surface along the second axis, wherein
the main surface, the edge surface, and the two walls of the edge fin form a closed cavity that extends along a third axis of the stacked conductance fin assembly, the third axis being perpendicular to the first axis and the second axis, and
Expression (2) is satisfied:
G1=H0/2 . . . (2)
where,
H0 is a length the main surface of the edge fin along the second axis, and
G1 is a length of each of the two offset walls of the edge fin along the second axis.
